(19) United States
(12) Patent Application Publication
(10) Pub. No.: US 2012/0261180 A1
(43) Pub. Date: Oct. 18, 2012

(54) Circuit Board

(75) Inventor: Yu-Bang Fu, Guishan Township (TW)

(73) Assignee: ALTEK CORPORATION, Hsinchu (TW)

(21) Appl. No.: 13/176,482

(22) Filed: Jul. 5, 2011

(30) Foreign Application Priority Data
Apr. 12, 2011 (TW) 100112657

(51) Int. Cl. H05K 1/11

(52) U.S. Cl. 174/266

(57) ABSTRACT

A circuit board is capable of reduce the effect of bowing. The circuit board comprises a substrate, a plurality of first vias, a plurality of second vias, and a plurality of first blocks. The substrate comprises a conductive layer outside the first blocks. The first vias pass through the substrate and the conductive layer. The first blocks would comprise the second vias, which passes through the substrate. The first vias and the first blocks can be individually or jointly disposed in a central area of the substrate, around a fastening hole, or around a circuit component. The fastening hole can be connected to at least one of the second vias by a conducting wire when the first block with the second vias is disposed around the fastening hole.

### BACKGROUND OF THE INVENTION

1. Field of the Invention

The present invention relates to a circuit board, and more particularly to a circuit board capable of reducing the bad influence caused by board bending.

2. Description of the Related Art

Quality of printed circuit board and restrict condition of electronic packaging must meet qualification and performance specification for rigid printed boards, IPC 6012 standard which defines SMT circuit board warpage or distortion of the maximum degree of 0.75%.

In the electronic packaging process, pin through hole (PTH) and surface mount technology (SMT) are generally applied in connection between circuit components and printed circuit board. Since electronic products are gradually developed to meet small size and light weight and multifunctional goals, printed circuit boards are usually bent to perform electronic packaging in accordance with demands of product structures. Bending printed circuit boards may cause different forces received over each unit area of the printed circuit board. In another word, bowing force may result in unbalancing stress in the printed circuit board. Consequently, although it still meets IPC 6012 standard, bowing still influences the adhesive effect between the circuit components and the circuit board to cause bad connection between the circuit components and the circuit board.

In addition, in the electronic packaging process, the circuit board is locked in a product by a fastening member passing through a fastening hole. During the locking process, a locking stress is generated around the fastening hole to cause unbalanced stress in the circuit board, resulting in bowing a central area of the circuit board, thereby influencing the contact effect between the circuit components and the circuit board.

To overcome bad connection between the circuit components and the circuit board caused by the influence of adhesive effect between the circuit components and the circuit board due to the bowing phenomenon generated on the printed circuit board resulting from the bending or the locked fastening member, a circuit board capable of reducing bowing influence is provided.

### SUMMARY OF THE INVENTION

In view of the shortcomings of the prior art, the inventor(s) of the present invention based on years of experience in the related industry to conduct extensive researches and experiments, and finally developed a circuit board as a principle objective that is capable of reducing the effect of bowing to overcome the influence of adhesive effect between the a circuit component and the circuit board.

To achieve the foregoing objective, a circuit board comprises a substrate and a plurality of first vias. The substrate comprises a conductive layer. The first vias pass through the substrate and the conductive layer, and the first vias can be disposed in a central area of the substrate or corners of the substrate.

The substrate can comprise a circuit component, and the first vias are disposed around the circuit component.

The substrate can comprise a plurality of fastening holes. The fastening hole passes through the substrate and the conductive layer to contain a fastening member, and the first vias can be disposed around the fastening hole.

According to another objective of the invention, a circuit board is provided and comprises a substrate and a plurality of first blocks. The substrate has a conductive layer outside the first block. The first block can be disposed in a central area of the substrate or corners of the substrate.

The substrate can comprise a circuit component, and the first vias are disposed around the circuit component.

The substrate can comprise a plurality of fastening holes. The fastening hole passes through the substrate and the conductive layer to contain a fastening member, and a predetermined area around the fastening hole is the first block.

According to a further objective of the invention, a circuit board is provided and comprises a substrate and a plurality of first blocks. The substrate has a conductive layer outside the first block. The first block can be disposed in a central area of the substrate or corners of the substrate.

The substrate can comprise a circuit component, and the first blocks are disposed around the circuit component.

The substrate can comprise a plurality of fastening holes. The fastening hole passes through the substrate to contain a fastening member, and a predetermined area around the fastening hole is the first block. In addition, at least one of the second vias and the fastening hole can be mutually connected by a conducting wire. The conducting wire is made of a conductive layer.

The circuit board according to the invention has one or multiple following advantages:
(1) The vias can be disposed on the substrate of the circuit board or around the circuit component of the circuit board. When the substrate is bowed, the bowing stress concentrating on the circuit board can be distributed through the deformation of the vias to reduce the bowing degree of the circuit board, thereby reducing adverse influence on the adhesive effect between the circuit component and the circuit board due to bowing. The bad connection between the circuit component and the circuit board can be prevented.
(2) The vias can be disposed around the fastening hole of the circuit board so that when the fastening hole receives the locking stress from the fastening member, the locking stress around the fastening hole can be distributed through the deformation of the vias.
(3) The circuit board can increase the softness degree of the substrate by laying the conductive layer to allow the substrate having higher softness degree to absorb the stress of the circuit board, thereby weakening the bowing degree.
(4) When no conductive layer is laid around the fastening hole of the circuit board, a conducting wire is disposed between the fastening hole and the vias so that the circuit board can be grounded by the fastening member to ensure electrostatic discharge (ESD) to prevent the circuit from being damaged.

### BRIEF DESCRIPTION OF THE DRAWINGS

FIG. 1 is a schematic diagram of a circuit board in accordance with a first embodiment of the invention;

FIG. 2 is a schematic diagram of a circuit board in accordance with a second embodiment of the invention;

FIG. 3 is a schematic diagram of a circuit board in accordance with a third embodiment of the invention;

FIG. 4 is a schematic diagram of a circuit board in accordance with a fourth embodiment of the invention;

FIG. 5 is a schematic diagram of a circuit board in accordance with a fifth embodiment of the invention;

FIG. 6 is a schematic diagram of a circuit board in accordance with a sixth embodiment of the invention;

FIG. 7 is a schematic diagram of a circuit board in accordance with a seventh embodiment of the invention;

FIG. 8 is a schematic diagram of a circuit board in accordance with an eighth embodiment of the invention;

FIG. 9 is a schematic diagram of a circuit board in accordance with a ninth embodiment of the invention;

FIG. 10 is a schematic diagram of a circuit board in accordance with a tenth embodiment of the invention;

FIG. 11 is a schematic diagram of a circuit board in accordance with an eleventh embodiment of the invention;

FIG. 12 is a schematic diagram of a circuit board in accordance with a twelfth embodiment of the invention;

FIG. 13 is a schematic diagram of a circuit board in accordance with a thirteenth embodiment of the invention; and

FIG. 14 is a schematic diagram of a circuit board in accordance with a fourteenth embodiment of the invention.

### DETAILED DESCRIPTION OF THE PREFERRED EMBODIMENTS

The foregoing and other technical characteristics of the present invention will become apparent with the detailed description of the preferred embodiments and the illustration of the related drawings.

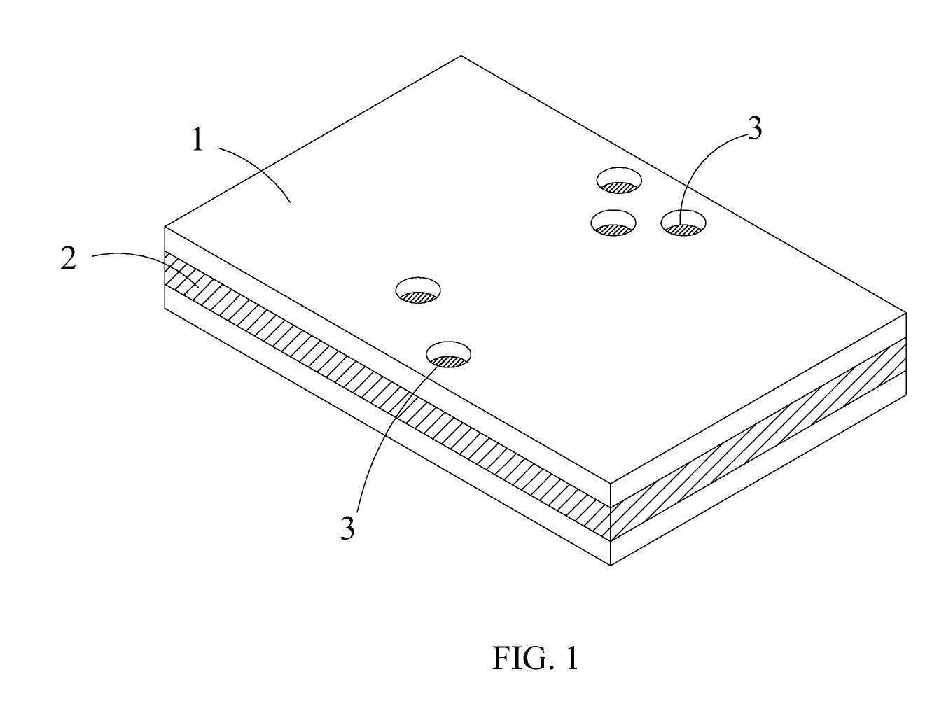

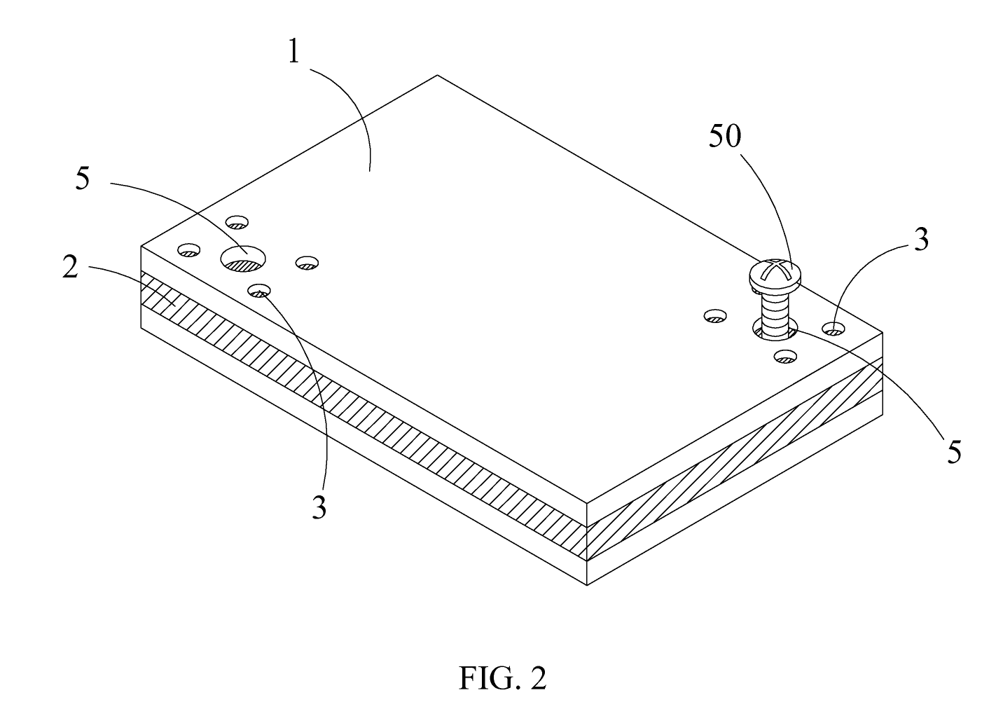

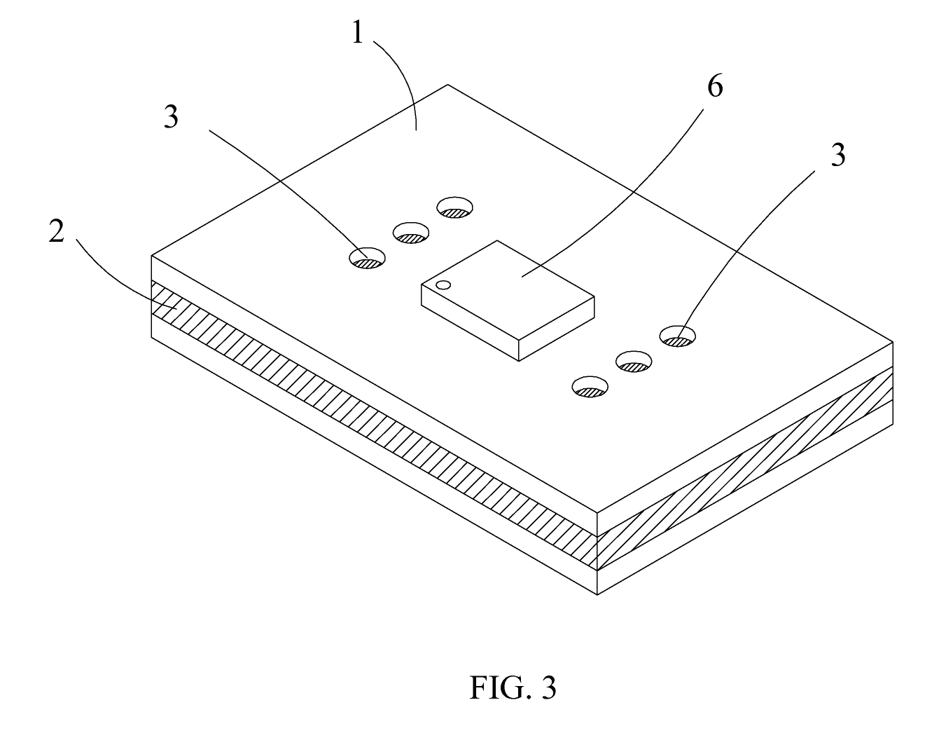

With reference to FIG. 1, FIG. 2 and FIG. 3, FIG. 1 is a schematic diagram of a circuit board in accordance with a first embodiment of the invention. FIG. 2 is a schematic diagram of a circuit board in accordance with a second embodiment of the invention. FIG. 3 is a schematic diagram of a circuit board in accordance with a third embodiment of the invention. The circuit board comprises a substrate 1, a plurality of first vias 3, a plurality of fastening holes 5 and a circuit component 6. The substrate 1 comprises a conductive layer 2 that can be a copper layer. The first vias 3 pass through the substrate 1 and the conductive layer 2.

According to a demand of electronic packaging, the first vias 3 can be disposed in a central area of the substrate 1. When the circuit board is twisted to cause deformation, the first vias 3 can be deformed to distribute the bowing stress concentrating on the circuit board so as to reduce the bowing degree of the circuit board.

According to a demand of electronic packaging, the first vias 3 can be disposed around the fastening hole 5. When the circuit board is locked and fastened in the electronic product by a fastening member 50, e.g. a metal screw, which passes through the fastening hole 5, the first vias 3 around the fastening hole 5 can be deformed to distribute the locking stress around the fastening hole 5 to avoid concentrating the locking stress on the central area of the circuit board, resulting in bowing the circuit board. Moreover, the circuit board can be grounded through the fastening member 50 to ensure electrostatic discharge, and thereby preventing circuits from being damaged.

In addition, according to a demand of electronic packaging, the first vias 3 can be disposed around the circuit component 6 which is an image sensor such as a multi-layer ceramic capacitor, a charge couple device (CCD), a complementary metal-oxide-semiconductor (CMOS). When the circuit board is twisted and bowed, the first vias 3 can be deformed to distribute the bowing stress concentrating on the circuit board to reduce the adverse influence of adhesive effect between the circuit component and the circuit board.

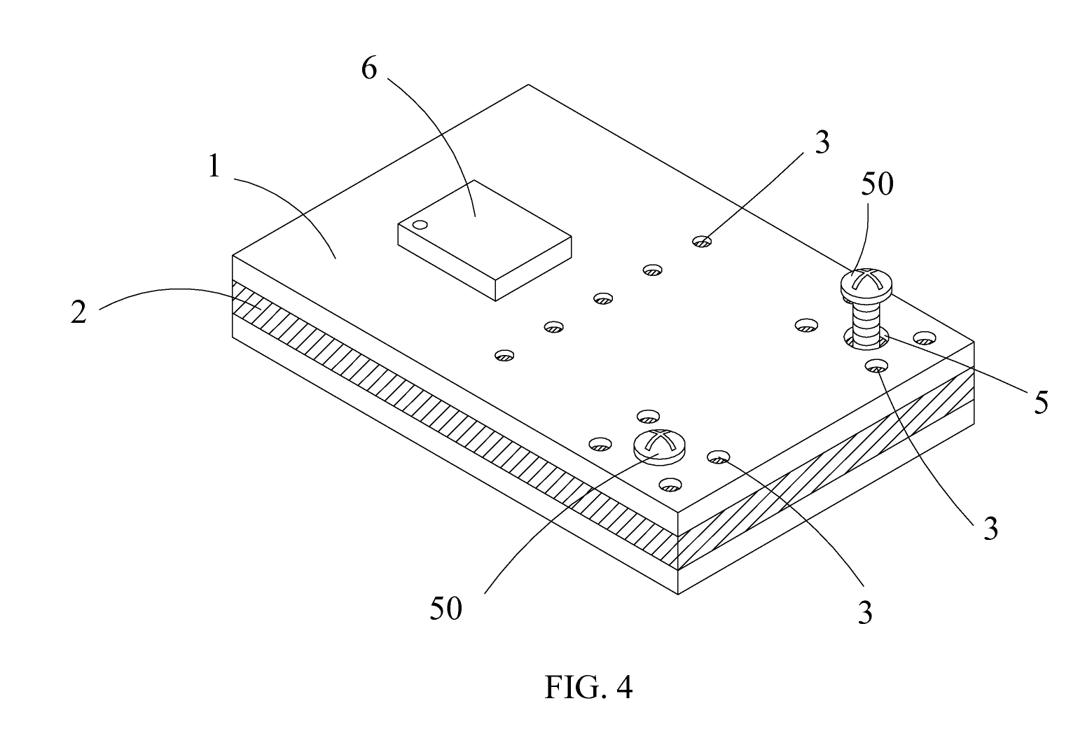

With reference to FIG. 4 for a schematic diagram of a circuit board in accordance with a fourth embodiment of the invention is depicted. According to a demand of electronic packaging, the first vias 3 can be simultaneously disposed at two or three of the following area, the central area of the substrate 1, the area around the fastening hole 5 or the area around the circuit component 6. Since the first vias 3 are deformed, the bowing degree of the circuit board is effectively reduced, and the adverse influence of adhesive effect between the circuit component and the circuit board can be decreased.

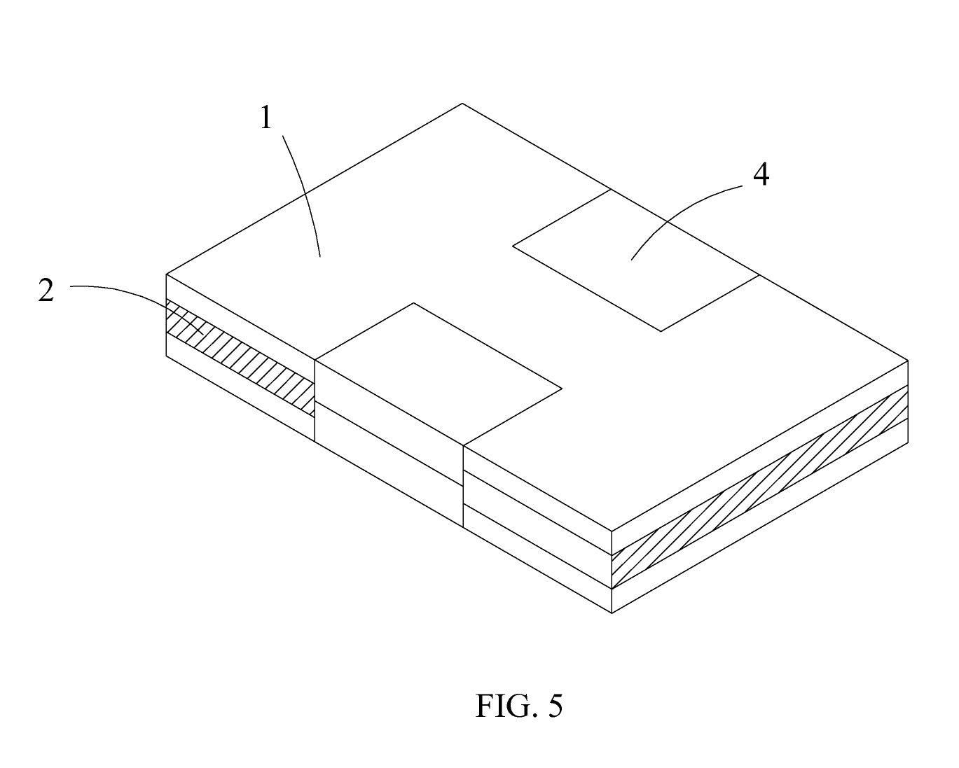

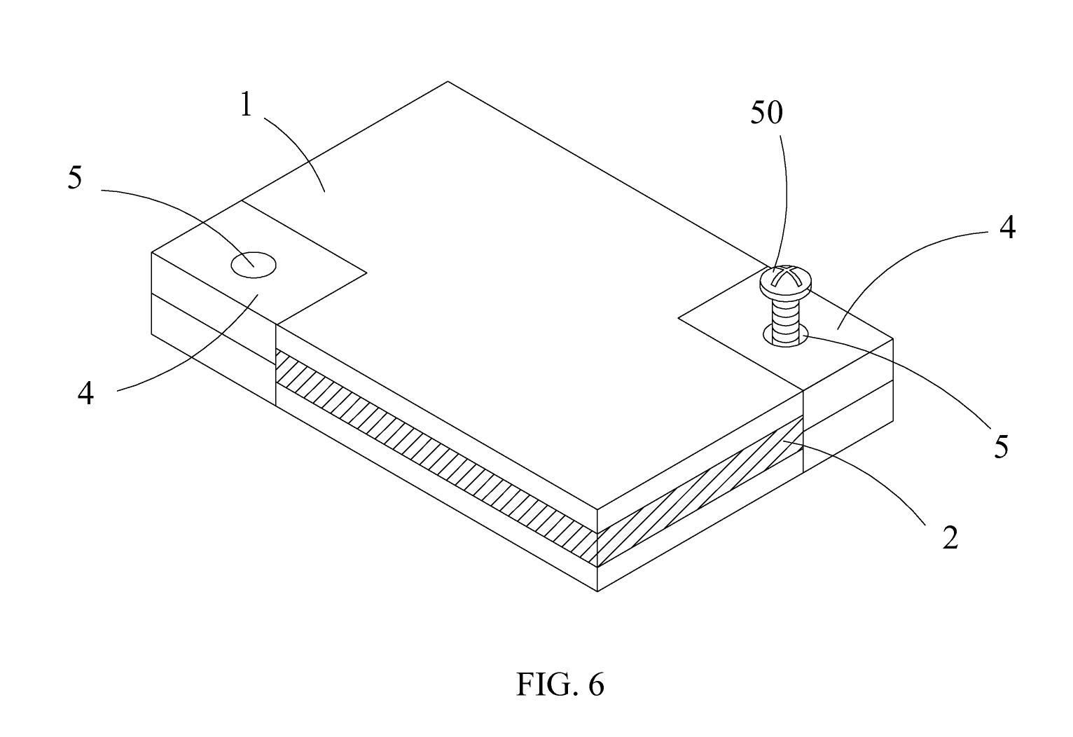

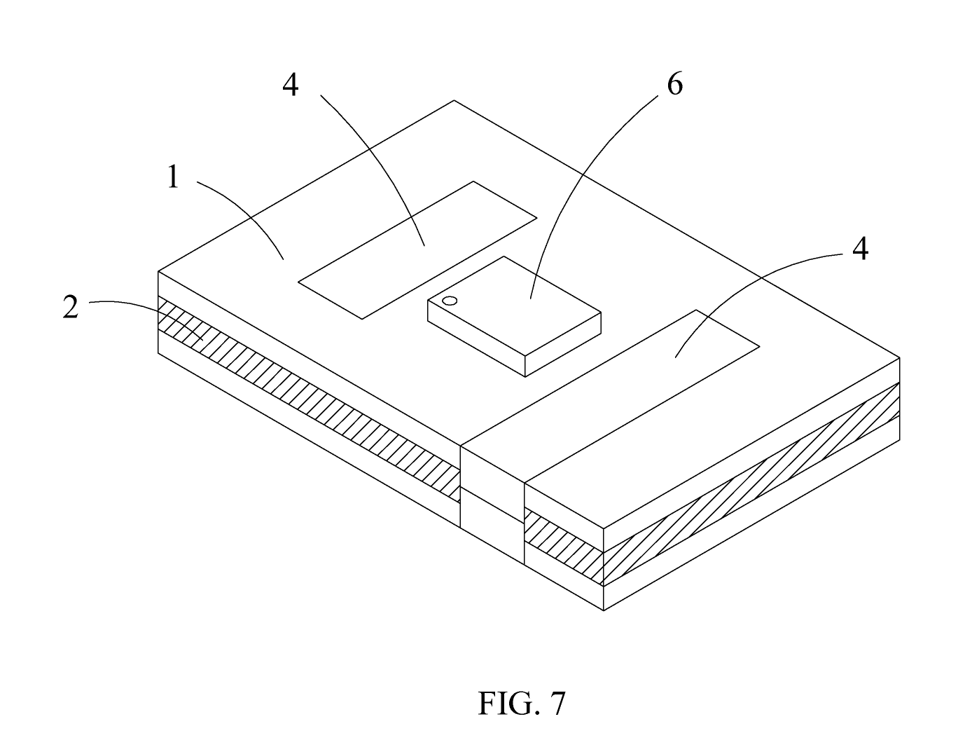

With reference to FIG. 5, FIG. 6 and FIG. 7, FIG. 5 is a schematic diagram of a circuit board in accordance with a fifth embodiment of the invention. FIG. 6 is a schematic diagram of a circuit board in accordance with a sixth embodiment of the invention. FIG. 7 is a schematic diagram of a circuit board in accordance with a seventh embodiment of the invention. The circuit board comprises a substrate, a plurality of first blocks 4, a plurality of fastening holes 5 and a circuit component 6. The substrate 1 comprises a conductive layer 2 outside the first blocks 4. The conductive layer 2 can be a copper layer. Since the first block 4 does not include the conductive layer 2, the first blocks 4 have higher softness degree than other area of the substrate 1.

According to a demand of electronic packaging, the first blocks 4 can be disposed in the central area of the substrate 1. When the circuit board is twisted and bowed, the first block 4 having higher softness degree can absorb the bowing stress concentrating on the circuit board to reduce the bowing degree of the circuit board.

According to a demand of electronic packaging, a predetermined area around the fastening hole 5 can be the first blocks 4. When the circuit board is locked and fastened in the electronic product by a fastening member 50, which can be a metal screw and passes through the fastening hole 5, the first blocks 4 with higher softness degree can absorb the locking stress around the fastening hole 5 to avoid concentrating the locking stress on the central area of the circuit board, resulting in the circuit board bowing.

According to a demand of electronic packaging, the first blocks 4 can be disposed around the circuit component 6 such as a multi-layer ceramic capacitor, a charge couple device (CCD), a complementary metal-oxide-semiconductor (CMOS) or other image sensors. When the circuit board is twisted and bowed, the first blocks 4 can absorb the bowing stress concentrating on the circuit board to reduce the adverse influence of adhesive effect between the circuit component and the circuit board.

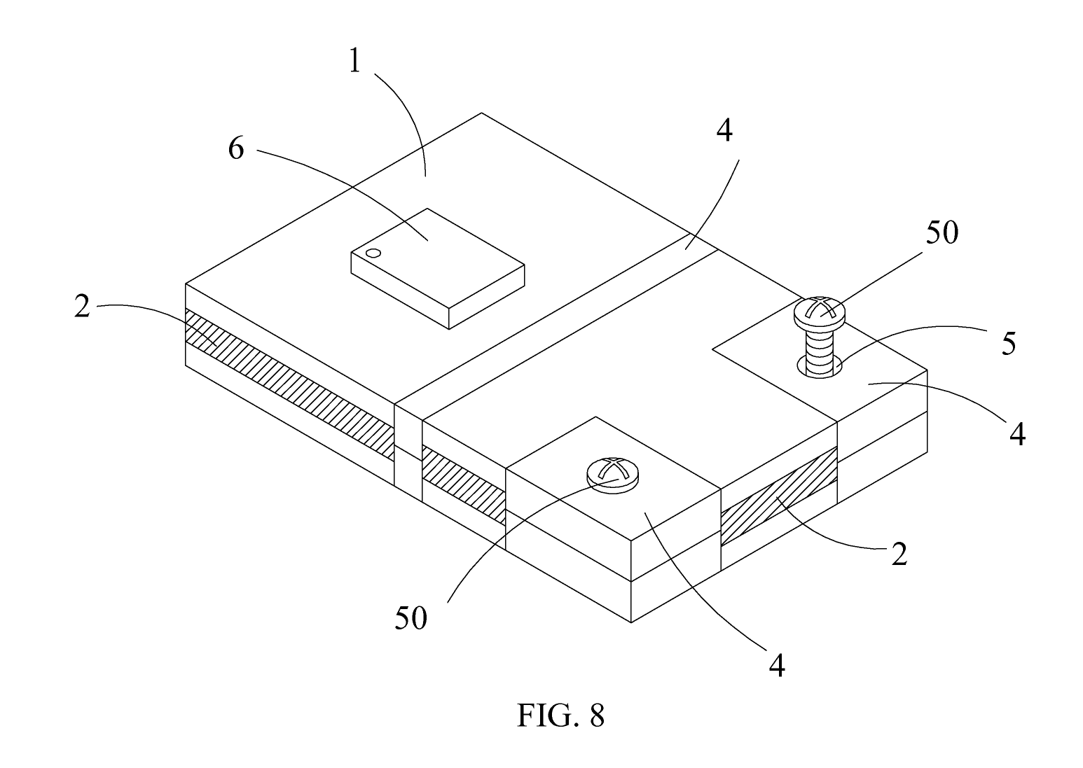

With reference to FIG. 5, FIG. 6 and FIG. 7 and please refer to FIG. 8 for a schematic diagram of a circuit board in accordance with an eighth embodiment of the invention. According to a demand of electronic packaging, the first blocks 4 can be simultaneously disposed at two or three of the following areas, the central area of the substrate 1, the area around the fastening hole 5 or the area around the circuit component 6. The bowing degree of the circuit board and the adverse influence of adhesive effect between the circuit component and the circuit board can be effectively reduced through the first blocks 4 having higher softness degree.

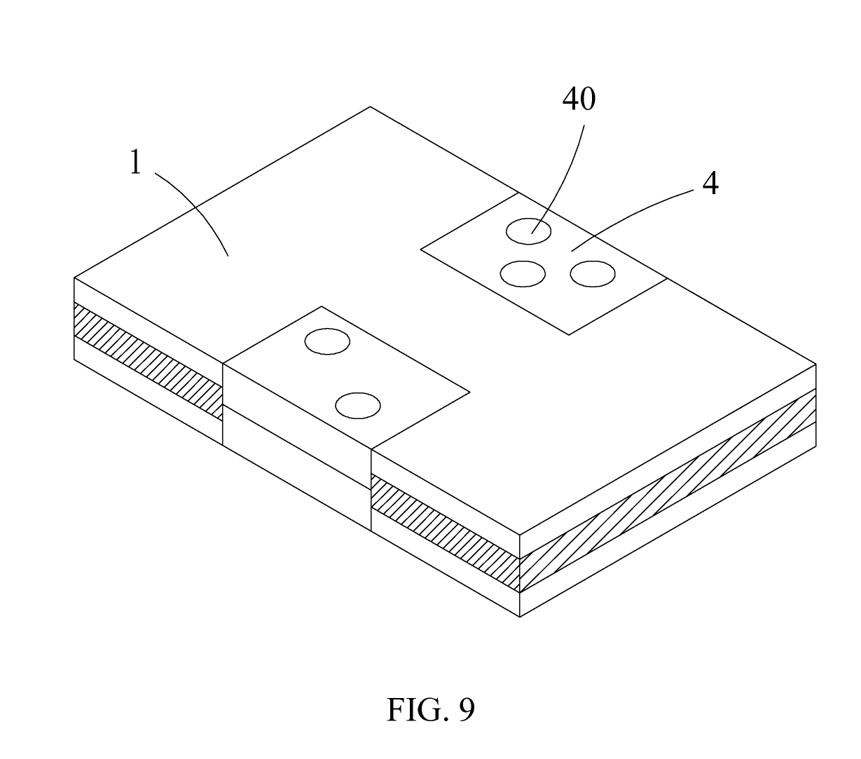

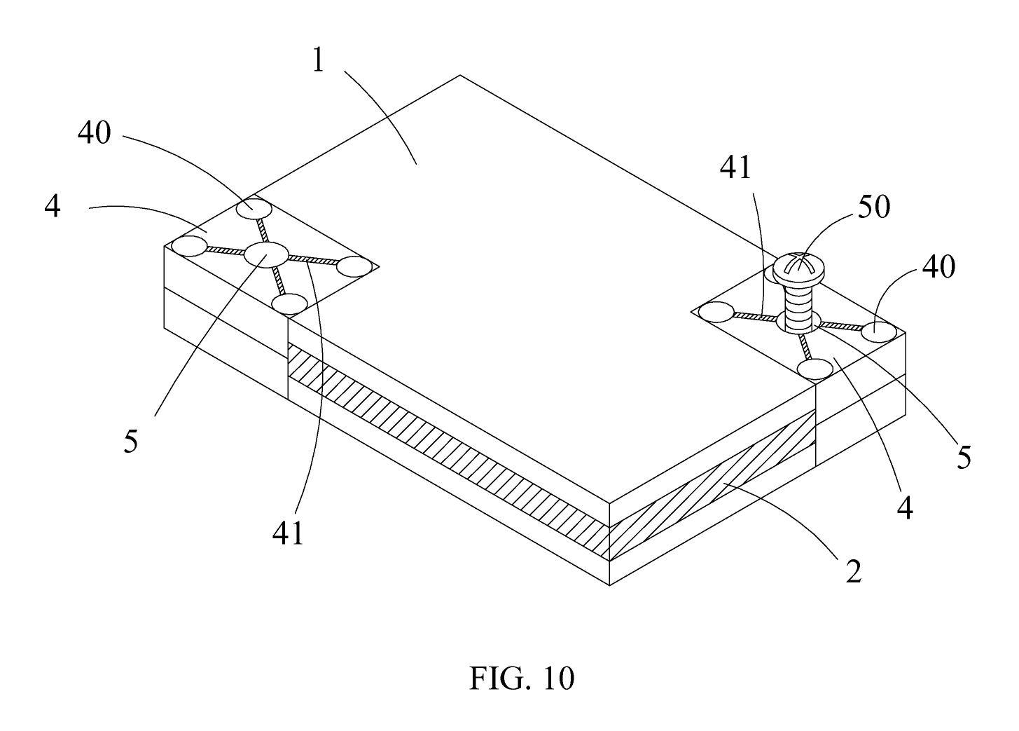

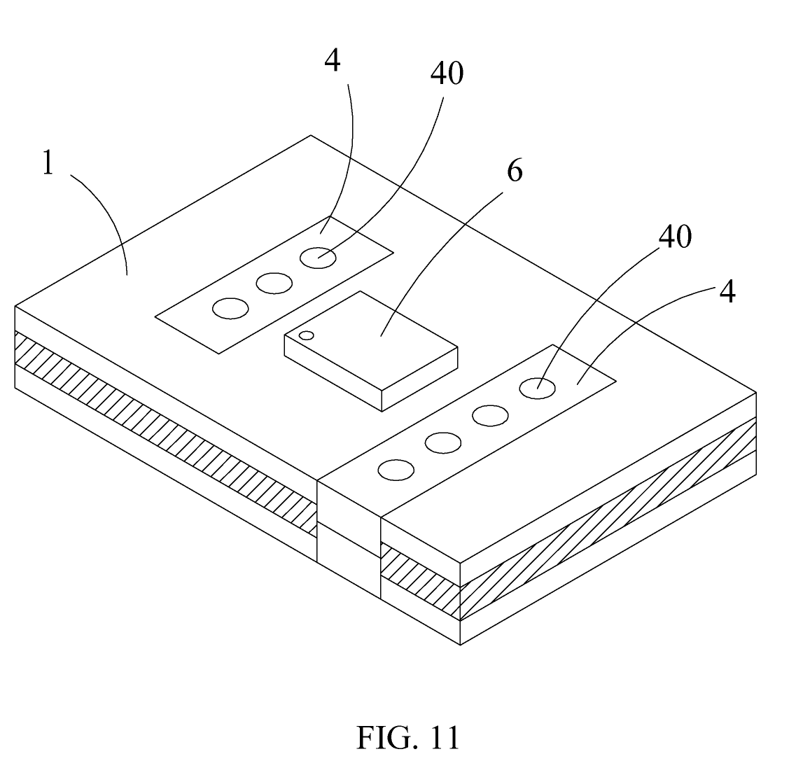

With reference to FIG. 9, FIG. 10 and FIG. 11, FIG. 9 is a schematic diagram of a circuit board in accordance with a ninth embodiment of the invention. FIG. 10 is a schematic diagram of a circuit board in accordance with a tenth embodiment of the invention. FIG. 11 is a schematic diagram of a circuit board in accordance with an eleventh embodiment of the invention. The circuit board comprises a substrate 1, a plurality of second vias 40, a plurality of first blocks 4, a plurality of fastening holes 5 and a circuit component 6. The substrate 1 comprises a conductive layer 2, which can be a copper layer, outside the first blocks 4. The first blocks 4 can include the second vias 40. Since the first block 4 does not include the conductive layer 2, the first blocks 4 have higher softness degree than other area of the substrate 1.

According to a demand of electronic packaging, the first blocks 4 can be disposed in the central area of the substrate 1. When the circuit board is twisted and bowed, the first blocks 4 having higher softness degree can absorb the bowing stress concentrating on the circuit board. Simultaneously, the second vias 40 can be deformed to distribute the bowing stress concentrating on the circuit board so as to reduce the bowing degree of the circuit board.

According to a demand of electronic packaging, the second vias 40 can be disposed around the fastening holes 5, and a predetermined area around the fastening hole 5 can be the first blocks 4. When the circuit board is locked and fastened in the electronic product by a fastening member 50, which can be a metal screw and passes through the fastening hole 5, the first blocks 4 with higher softness degree can absorb the locking stress around the fastening holes 5. Simultaneously, the second vias 40 are deformed to distribute the locking stress around the fastening holes 5 to avoid concentrating the locking stress on the central area of the circuit board, resulting in the circuit board bowing.

In addition, at least one of the second vias 40 and the fastening holes 5 can be mutually connected by a conducting wire 41. The conducting wire 41 is composed of a conductive layer 2 such as a copper wire. The circuit board can be grounded through the fastening member 50 to ensure electrostatic discharge, and thereby preventing circuits from being damaged.

According to a demand of electronic packaging, the first blocks 4 can be disposed around the circuit component 6 such as a multi-layer ceramic capacitor, a charge couple device (CCD), a complementary metal-oxide-semiconductor

(CMOS) or other image sensors. When the circuit board is twisted and bowed, the first blocks 4 can absorb the bowing stress concentrating on the circuit board. Simultaneously, the second vias 40 can be deformed to distribute the bowing stress concentrating on the circuit board so as to reduce the adverse influence of adhesive effect between the circuit component and the circuit board.

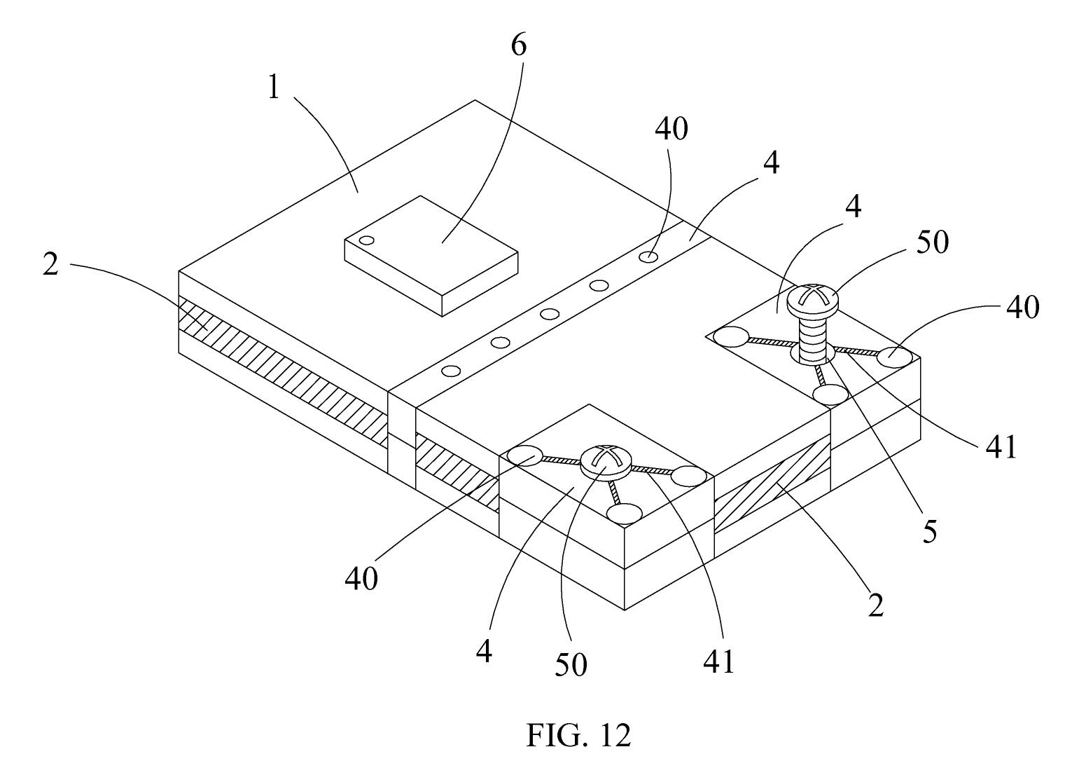

With reference to FIG. 12 for a schematic diagram of a circuit board in accordance with a twelfth embodiment of the invention is depicted. The first blocks 1 containing the second vias 40 can be simultaneously disposed at two or three of the following areas ,the central area of the substrate 1, the area around the fastening hole 5 or the area around the circuit component 6. The stress in the circuit board can be distributed through the first blocks 4 having higher softness degree and the deforming of the second vias 40. The bowing degree of the circuit board and the adverse influence of adhesive effect between the circuit component and the circuit board can be effectively reduced through the foregoing dual manners.

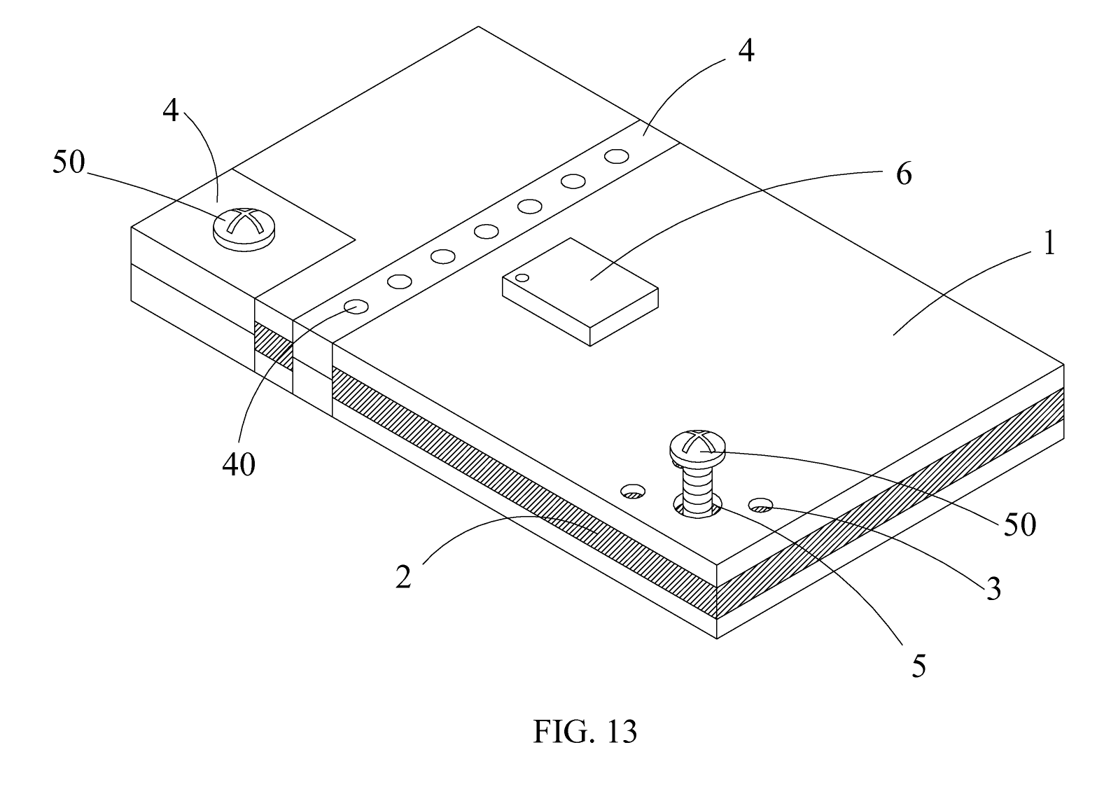

With reference to FIG. 13 for a schematic diagram of a circuit board in accordance with a thirteenth embodiment of the invention is depicted. The circuit board comprises a substrate 1, a plurality of first vias 3, a plurality of second vias 40, a plurality of first blocks 4, a plurality of fastening holes 5 and a circuit component 6. The substrate 1 comprises a conductive layer 2, which can be a copper layer, outside the first blocks 4. The first vias 3 pass through the substrate 1 and the conductive layer 2. Since the first blocks 4 do not include the conductive layer 2, the first blocks 4 have higher softness degree than other area of the substrate 1.

According to a demand of electronic packaging, the first vias 3 are disposed around of the fastening holes 5 of the substrate 1. When the circuit board is locked and fastened in the electronic product by a fastening member 50, which can be a metal screw and passes through the fastening hole 5, the first vias 3 can be bowed to distribute the locking stress around the fastening hole 5 to avoid concentrating the locking stress over the central area of the circuit board, resulting in the circuit board bowing. Moreover, the circuit board can be grounded by the fastening member 50 to ensure electrostatic discharge so as to prevent the circuits from being damaged.

According to a demand of electronic packaging, the first blocks 4 can be disposed around the circuit component 6 such as a multi-layer ceramic capacitor, a charge couple device (CCD), a complementary metal-oxide-semiconductor (CMOS) or other image sensors. The first blocks 4 comprise the second vias 40, and the second vias 40 pass through the substrate 1. When the circuit board is twisted and bowed, the first blocks 4 can absorb the bowing stress concentrating on the circuit board. The second vias 40 can be deformed to distribute the bowing stress concentrating on the circuit board so as to reduce the adverse influence of adhesive effect between the circuit component and the circuit board.

According to a demand of electronic packaging, a first block is disposed on a predetermined area around the fastening hole 5 of the substrate 1. When the fastening member 50 passes through the fastening hole 5 to lock and fasten the circuit board in the electronic product, the first block 4 having higher softness degree can absorb the locking stress around the fastening hole 5 to avoid concentrating the locking stress over the central area of the circuit board, resulting in the circuit board bowing.

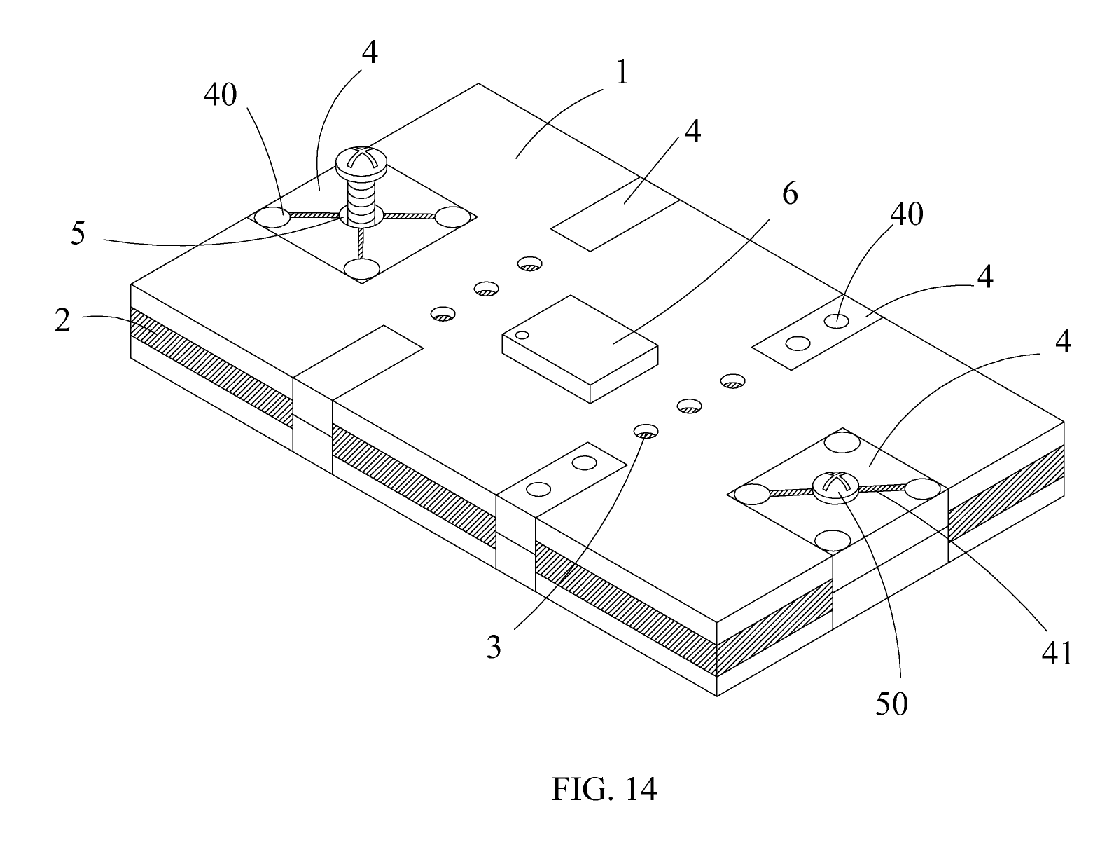

With reference to FIG. 13 and FIG. 14 for a schematic diagram of a circuit board in accordance with a fourteenth embodiment of the invention is depicted. According to a demand of electronic packaging, the second vias 40 are disposed around the fastening hole 5 at two opposite sides of the substrate 1. A predetermined area around the fastening hole 5 is the first blocks 4, and the second vias 40 pass through the substrate 1. When a fastening member 50, such as a metal screw, passes through the fastening hole 5 to lock and fastening the circuit board in the electronic board, the second vias 40 can be deformed to distribute the locking stress around the fastening hole 5 to avoid concentrating the locking stress over the central area of the circuit board. Moreover, the fastening hole 5 and at least one of the second vias 40 can be mutually connected through a conducting wire 41. The conducting wire 41 can be made of the conductive layer 2 such as a copper wire. Accordingly, the circuit board can be grounded through the fastening member 50 to ensure the electrostatic discharge to prevent the circuit from being damaged.

According to a demand of electronic packaging, the two first blocks 4 are respectively disposed at two opposite sides of the central area of the substrate 1, wherein one of the first blocks 4 comprises the second vias 40. When the circuit board is twisted and bowed, the two sets of the first blocks 4 can absorb the bowing stress concentrating on the circuit board. At the same time, the second vias 40 at one of the first blocks 4 can be deformed to distribute the bowing stress concentrating on the circuit board to avoid concentrating the locking stress over the central area of the circuit board.

According to a demand of electronic packaging, the first vias 3 are respectively disposed at two opposite sides around the circuit component 6 such as a multi-layer ceramic capacitor, a charge couple device (CCD), a complementary metal-oxide-semiconductor (CMOS) or other image sensors. When the circuit board is twisted and bowed, the first vias 3 can be deformed to distribute the bowing stress concentrating on the circuit board to weaken the adverse influence of adhesive effect between the circuit component and the circuit board.

To sum up, the first vias pass through the substrate and the conductive layer, and the first via can be individually disposed in the central area of the substrate, around the fastening hole or around the circuit component. Alternatively, the first vias can be simultaneously disposed at two or three of the following areas, the central area of the substrate, the area around the fastening hole or the area around the circuit component. The substrate has the conductive layer outside the first block. The first block can also include the second via. The second vias pass through the substrate. The first block can be individually disposed in the central area of the substrate, around the fastening hole or around the circuit component. Alternatively, the first block can be simultaneously disposed at two or three of the following areas, the central area of the substrate, the area around fastening fixation hole and the area around the circuit component.

Further, according to a demand of electronic packaging, the first via and the first block can be selectively disposed at two or three of the following areas, the central area of the substrate, the area around the fastening hole and the area around the circuit component. When the first block having higher softness degree absorbs the stress in the circuit board and the vias are deformed to distribute the bowing stress concentrated on the circuit board, the status of circuit board bowing can be reduced, and the adverse influence of adhesive effect between the circuit component and the circuit board can be weakened to avoid bad contact between the circuit component and the circuit board.

The invention improves over the prior art and complies with patent application requirements, and thus is duly filed for patent application. While the invention has been described by device of specific embodiments, numerous modifications and variations could be made thereto by those generally skilled in the art without departing from the scope and spirit of the invention set forth in the claims.

What is claimed is:

1. A circuit board comprising:
a substrate comprising a conductive layer; and
a plurality of first vias passing through the substrate and the conductive layer and disposed to a central area of the substrate or corners of the substrate.

2. The circuit board as recited in claim 1, wherein the substrate further comprises a circuit component, and the first vias are disposed around the circuit component.

3. The circuit board as recited in claim 1, wherein the substrate further comprises a plurality of fastening holes, and each fastening hole passes through the substrate and the conductive layer to contain a fastening member, and the first vias are disposed around each fastening hole.

4. A circuit board comprising:
a substrate; and
a plurality of first blocks disposed to a central area of the substrate or corners of the substrate, the substrate having a conductive layer outside the first blocks.

5. The circuit board as recited in claim 4, wherein the substrate further comprises a circuit component, and the first blocks are disposed around the circuit component.

6. The circuit board as recited in claim 4, wherein the substrate further comprises a plurality of fastening holes, and each fastening hole passes through the substrate to contain a fastening member, and a predetermined area around each fastening hole is the first block.

7. A circuit board comprising:
a substrate;
a plurality of second vias passing through the substrate; and
a plurality of first blocks comprising the second vias and being disposed in a central area of the substrate or corners of the substrate, the substrate having a conductive layer outside the first blocks.

8. The circuit board as recited in claim 7, wherein the substrate further comprises a circuit component, and the first blocks are disposed around the circuit component.

9. The circuit board as recited in claim 7, wherein the substrate further comprises a plurality of fastening holes, and each fastening hole passes through the substrate to contain a fastening member, and the second vias are disposed around each fastening hole, and a predetermined area around each fastening hole is the first block.

10. The circuit board as recited in claim 9, wherein each fastening hole and at least one of the second vias are mutually connected by a conducting wire, and the conducting wire is made of the conductive layer.
